(19) United States
(12) Patent Application Publication
(10) Pub. No.: US 2023/0117490 A1
(43) Pub. Date: Apr. 20, 2023

(54) SEMICONDUCTOR ELEMENT ARRANGEMENT STRUCTURE

(71) Applicant: EPISTAR CORPORATION, Hsinchu (TW)

(72) Inventors: Chang-Tai HSIAO, Hsinchu (TW); Ying-Yang SU, Hsinchu (TW)

(21) Appl. No.: 17/966,683

(22) Filed: Oct. 14, 2022

Related U.S. Application Data
(60) Provisional application No. 63/262,524, filed on Oct. 14, 2021.

(51) Int. Cl. H01L 21/683; H01L 25/075; H01L 33/46; H01L 33/62

(52) U.S. Cl. CPC H01L 21/6835; H01L 25/0753; H01L 33/46; H01L 33/62; H01L 2221/68318; H01L 2221/68354; H01L 2221/68368; H01L 2221/68381

(57) ABSTRACT

A semiconductor element arrangement structure is provided. The semiconductor element arrangement structure includes a carrier substrate, first and second adhesive layers respectively disposed on the carrier substrate and separated from each other, and first and second semiconductor elements disposed on the first and second adhesive layers, respectively. The first semiconductor element has first and second electrodes on the same side of the first semiconductor element, and the second semiconductor element has third and fourth electrodes on the same side of the second semiconductor element. The first adhesive layer is in direct contact with the first and second electrodes, and the second adhesive layer is in direct contact with the third and fourth electrodes. The first adhesive layer has a first width between the first and second electrodes and has a second width not between the first and second electrodes that is less than the first width.

### CROSS REFERENCE TO RELATED APPLICATIONS

This application claims the benefit of U.S. Provisional Application No. 63/262,524, filed on Oct. 14, 2021, and the entirety of which is incorporated by reference herein.

### BACKGROUND

### Technical Field

The application relates to a semiconductor element arrangement structure, and in particular, to a semiconductor element arrangement structure including an adhesive layer.

### Description of the Related Art

Light-emitting diodes (LEDs), benefitted from low energy consumption and longer lifespan, are gradually replacing conventional light sources, such as incandescent lamps and fluorescent light bulbs. The LEDs can be applied to many kinds of fields, such as traffic signals, backlight modules, street lights, and medical equipments. Since the light emitted by LEDs belongs to monochromatic light, LEDs are also suitable for being used as pixels in the display devices.

Nowadays, LEDs have been used as display pixels in many kinds of display devices. To fulfill the requirement of higher resolution, the LED is continuously reducing its size, and the number of the LEDs required in a single display device is also increasing. Therefore, in production of LED display devices, it becomes an important technical issue to precisely and efficiently transfer millions of miniatured LEDs.

### BRIEF SUMMARY OF THE DISCLOSURE

In some embodiments of the application, a semiconductor element arrangement structure is provided. The semiconductor element arrangement structure includes a carrier substrate, a first adhesive layer and a second adhesive layer respectively disposed on the carrier substrate and separated from each other, and a first semiconductor element and a second semiconductor element disposed on the first adhesive layer and the second adhesive layer, respectively. The first semiconductor element has a first electrode and a second electrode arranged on the same side thereof, and the second semiconductor element has a third electrode and a fourth electrode arranged on the same side thereof. The first adhesive layer is in direct contact with the first and second electrodes, and the second adhesive layer is in direct contact with the third and fourth electrodes. The first adhesive layer has a first width which is located between the first and second electrodes, and a second width which is not located between the first and second electrodes and less than the first width.

A detailed description is given in the following embodiments with reference to the accompanying drawings.

### BRIEF DESCRIPTION OF THE DRAWINGS

The application may be more fully understood by reading the subsequent detailed description and embodiments with reference to the accompanying drawings, wherein:

FIGS. 1A, 1B, and 2 are cross-sectional views of semiconductor element arrangement structures in accordance with some embodiments.

FIG. 3 is a cross-sectional view showing the detailed structure of the semiconductor element shown in FIG. 2 in accordance with some embodiments.

FIGS. 4A and 4B are cross-sectional views of semiconductor element arrangement structures in accordance with different embodiments.

FIGS. 5A-5D are enlarged cross-sectional views of the region R in FIG. 4A in accordance with different embodiments.

FIGS. 6 and 7 show the process of transferring semiconductor elements in accordance with some embodiments.

FIG. 8 is a cross-section view of a semiconductor element arrangement structure in accordance with other embodiments.

FIGS. 9 and 10 show a cross-sectional view and a top view of the semiconductor element arrangement structure after transferring part of the semiconductor elements in accordance with other embodiments, respectively.

FIGS. 11A and 11B show cross-sectional views of semiconductor element arrangement structures in accordance with different embodiments.

FIGS. 12 and 13 show the process of transferring the semiconductor elements in accordance with some other embodiments.

### DETAILED DESCRIPTION OF THE DISCLOSURE

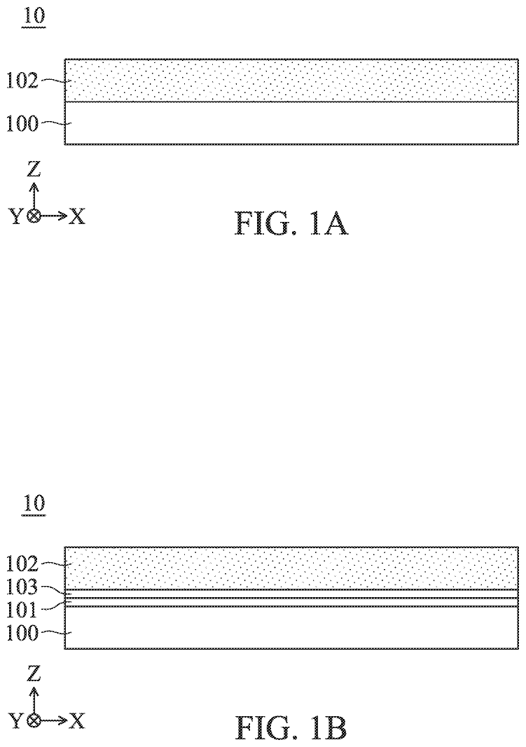

FIGS. 1A, 1B, and 2 show cross-sectional views of a semiconductor element arrangement structure 10 at specific stages in accordance with some embodiments. Referring to FIG. 1A, the semiconductor element arrangement structure 10 includes a carrier substrate 100 and an adhesive material layer 102 located on the carrier substrate 100. In some embodiments, the material of the carrier substrate 100 includes quartz, glass, sapphire, a polymer material, or a combination thereof. In one embodiment, the carrier substrate 100 is light-transmittable. Specifically, the carrier substrate 100 allows the light with a specific wavelength spectrum emitted by semiconductor elements to pass through, or allows the light with a specific wavelength spectrum able to be absorbed by the semiconductor elements to pass through. In some embodiments, the material of the adhesive material layer 102 includes a UV curing film, a thermal curing film, or a combination thereof, such as benzocyclobutene (BCB), acrylic, epoxy resin, or acrylic epoxy resin. The semiconductor elements which are electronic devices formed of semiconductor materials, can be light-emitting diodes (LEDs), laser diodes (LDs), or transistors.

Referring to FIG. 1B, in some embodiments, the semiconductor element arrangement structure 10 further includes an auxiliary adhesive layer 101 and a base material layer 103. The auxiliary layer 101 is located between the carrier substrate 100 and the adhesive material layer 102, and the base material layer 103 is located between the auxiliary adhesive layer 101 and the adhesive material layer 102. The base material layer 103 supports the adhesive material layer 102 to provide the semiconductor element arrangement structure 10 a better structural stability. In some embodiments, the material of the auxiliary adhesive layer 101 includes a pressure-sensitive adhesive or a thermoplastic elastomer (TPE), such as acrylic, silicone, polyurethane (PU), or combinations thereof.

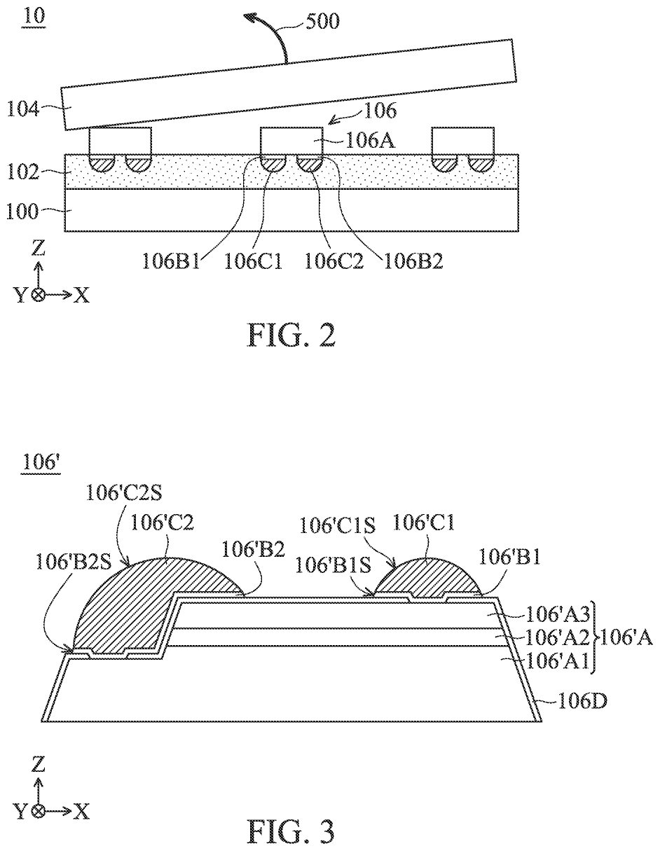

Referring to FIG. 2, semiconductor elements 106 are transferred from a primary substrate 104 to the adhesive material layer 102. The primary substrate 104 is a material used to form the semiconductor elements 106, or is an object used to temporarily carry the semiconductor elements 106 before the semiconductor elements 106 are transferred to the adhesive material layer 102. The semiconductor element 106 includes a semiconductor stack 106A, and electrodes 106B1 and 106B2 that are located on the same side of the semiconductor element 106. In some embodiments, the semiconductor element 106 further includes conductive bumps 106C1 and 106C2 correspondingly disposed on the electrodes 106B1 and 106B2. The semiconductor elements 106 shown in FIG. 2 and the following figures are illustrative. In some embodiments, as the detailed structure shown in FIG. 3, the semiconductor element 106 is a light-emitting diode (LED) 106′.

First, referring to FIG. 2, the primary substrate 104 is inverted so that the electrodes 106B1 and 106B2 and the conductive bumps 106C1 and 106C2 of the semiconductor elements 106 face toward the adhesive material layer 102. Subsequently, the semiconductor elements 106 are disposed on the adhesive material layer 102, and the electrodes 106B1 and 106B2 and the conductive bumps 106C1 and 106C2 sink into the adhesive material layer 102. Finally, a removal process 500 is performed to remove the primary substrate 104. In some embodiments, the removal process 500 is a laser lift-off (LLO) process. In some embodiments, the semiconductor elements 106 on the adhesive material layer 102 is electrically isolated from the carrier substrate 100.

In accordance with some embodiments, the material of the primary substrate 104 includes Ge, GaAs, InP, Sapphire, SiC, Si, LiAlO₂, ZnO, GaN, AlN, metal, glass, composite, diamond, CVD diamond, diamond-like carbon (DLC), or combinations thereof.

FIG. 3 is a cross-sectional view of the detailed structure when the semiconductor element 106 shown in FIG. 2 is the LED 106′ in accordance with some embodiments. Referring to FIG. 3, the semiconductor stack 106′A of the LED 106′ includes a first conductive type semiconductor layer 106′A1, a light-emitting layer 106′A2 on the first conductive type semiconductor layer 106′A1, and a second conductive type semiconductor layer 106′A3 on the light-emitting layer 106′A2. The overall thickness of the semiconductor stack 106′A is equal to or less than 10 μm. The first conductive type semiconductor layer 106′A1, the light-emitting layer 106′A2, and the second conductive type semiconductor layer 106′A3 each includes a III-V semiconductor material, such as a GaN-based material, a InGaN-based material, a AlGaN-based material, a AlInGaN-based material, a GaP-based material, a InGaP-based material, a AlGaP-based material, or a AlInGaP-based material, its general formula is represented by AlₓIn_{y}Ga_{(1-x-y)}N or AlₓIn_{y}Ga_{(1-x-y)}P, in which 0≤x≤1, 0≤y≤1, and (x+y)≤1. According to the property of the material, the LED 106′ may emit infrared light, red light, green light, blue light, near UV light, or UV light. For example, when the materials of the first conductive type semiconductor layer 106′A1, the light-emitting layer 106′A2, and the second conductive type semiconductor layer 106′A3 in the semiconductor stack 106′A are AlInGaP-based materials, the LED 106′ can emit red light with a wavelength between 610 nm and 650 nm. When the materials of the first conductive type semiconductor layer 106′A1, the light-emitting layer 106′A2, and the second conductive type semiconductor layer 106′A3 in the semiconductor stack 106′A are InGaN-based materials, the LED 106′ can emit blue light with a wavelength between 400 nm and 490 nm or green light with a wavelength between 530 nm and 570 nm. When the materials of the first conductive type semiconductor layer 106′A1, the light-emitting layer 106′A2, and the second conductive type semiconductor layer 106′A3 in the semiconductor stack 106′A are AlGaN-based materials or AlInGaN-based materials, the LED 106′ can emit UV light with a wavelength between 250 nm and 400 nm.

Referring again to FIG. 3, the LED 106′ further includes an insulating layer 106D. The insulating layer 106D covers the semiconductor stack 106′A. In particular, the insulating layer 106D is conformally formed on the top surface and the sidewall of the semiconductor stack 106′A. Accordingly, the insulating layer 106D has a uniform thickness at its portions that are located on the semiconductor stack 106′A and on the sidewall of the semiconductor stack 106′A. In addition, the insulating layer 106D has openings on the first conductive type semiconductor layer 106′A1 and the second conductive type semiconductor layer 106′A3. The electrodes 106′B1 and 106′B2 of the LED 106′ are filled into these openings and electrically connected to the second conductive type semiconductor layer 106′A3 and the first conductive type semiconductor layer 106′A1, respectively.

In some embodiments, the insulating layer 106D is a single-layer structure or a multi-layer structure. The material of the insulating layer 106D includes silicon oxide, silicon nitride, silicon oxynitride, niobium oxide, hafnium oxide, titanium oxide, magnesium fluoride, aluminum oxide, or a combination thereof. In one embodiment, the insulating layer 106D includes a distributed Bragg reflector (DBR) structure. In particular, the DBR structure is formed of one or more pairs of alternately stacked insulating materials with varying refractive indices. With insulating materials having varying refractive indices and specific thicknesses, the DBR structure can reflect light with a specific wavelength range and/or with a specific range of incident angles. In some embodiments, the insulating layer 106D includes a stack of the DBR structure and other insulating materials.

As shown in FIG. 3, the electrodes 106′B1 and 106′B2 of the LED 106′ are formed on the insulating layer 106D and filled into the openings of the insulating layer 106D. Therefore, the electrode 106′B1 is conformally formed on the second conductive type semiconductor layer 106′A3 and the insulating layer 106D, and the electrode 106′B2 is conformally formed on the first conductive type semiconductor layer 106′A1, the light-emitting layer 106′A2, the second conductive type semiconductor layer 106′A3, and the insulating layer 106D. In addition, the electrodes 106′B1 and 106′B2 respectively have outermost electrode surfaces 106′B1S and 106′B2S. In some embodiments, the electrodes 106B1 and 106B2 are made of materials capable of forming electrical connection with the materials of the semiconductor stack and withstanding the subsequent processes. The material include metal, such as Au, Ag, Cu, Cr, Al, Pt, Ni, Ti, an alloy thereof, or a stack thereof.

The conductive bumps 106′C1 and 106′C2 are directly connected to the electrodes 106′B1 and 106′B2, respectively. In some embodiments, the conductive bumps 106′C1 and 106′C2 have curved profiles. Specifically, the conductive bumps 106′C1 and 106′C2 have curved contours which are smooth and bulged outwardly, and have outermost bump surfaces 106′C1S and 106′C2S. With the curved outermost bump surfaces 106′C1S and 106′C2S, the LEDs 106′ can be more evenly adhered to a target substrate in the transferring and bonding processes, which elevates the operation stability of LEDs 106′. In some embodiments, the conductive bumps 106′C1 and 106′C2 are made of materials capable of forming physical and electrical connection with electrodes 106′B1 and 106′B2 and external structures. Specifically, the materials suitable for the conductive bumps include a metal with a low melting point or an alloy with a low liquidus melting point whose melting temperature or liquidus melting temperature is less than 210° C. For example, the metal with a low melting point or the alloy with a low liquidus melting point is bismuth (Bi), tin (Sn), indium (In), or an alloy thereof. In one embodiment, the materials of the conductive bumps 106′C1 and 106′C2 include a tin-indium alloy or a tin-bismuth alloy. In some embodiments, the melting temperature of the metal with the low melting point or the liquidus melting temperature of the alloy with the low liquidus melting point is less than 170° C.

The conductive bump 106′C1 is located directly above the electrode 106′B1. As shown in FIG. 3, a recess is located around the center of the electrode 106′B1. That is, the outermost electrode surface 106′B1S of the electrode 106′B1 is not a flat surface and has a recess. The conductive bump 106′C1 directly covers the electrode 106′B1. The outermost bump surface 106′ C1S of the conductive bump 106′ Cl has a convexly curved shape, and is not parallel with the outermost electrode surface 106′B1S of the electrode 106′B1. The conductive bump 106′ C2 is directly located above the electrode 106′B2. The outer profile of the electrode 106′B2 close to the semiconductor stack 106′A has a stepwise shape. That is, the outermost electrode surface 106′B2S of the electrode 106′B2 is not a flat surface and has a stepwise portion. The conductive bump 106′C2 directly covers the electrode 106′B2. The outermost bump surface 106′C2S of the conductive bump 106′C2 has a convexly curved shape, and is not parallel with the outermost electrode surface 106′B2S of the electrode 106′B2. Preferably, the highest points of the conductive bumps 106′C1 and 106′C2 are substantially located at the same elevation, which is beneficial to firmly fix the LED 106′ on a structure, such as the adhesive material layer 102.

In some embodiments, there are granules (not shown) with irregular shapes randomly dispersed in the conductive bumps 106′C1 and 106′C2. The granules have a material different from that of the conductive bumps 106′C1 and 106′C2, but has a material same as that of a part of the electrodes 106′B1 and 106′B2, such as gold. In some embodiments, the outermost bump surfaces 106′C1S and 106′C2S of the conductive bumps 106′C1 and 106′C2 are smooth surfaces with roughness less than that of the uppermost surface of the semiconductor stack 106′A. Specifically, the conductive bumps 106′C1 and 106′C2 and the outermost electrode surfaces 106′B1S and 106′B2S of the underlying electrodes 106′B1 and 106′B2 have different profiles. For example, the outermost bump surfaces 106′C1S and 106′C2S of the conductive bumps 106′C1 and 106′C2 do not have recesses. In addition, the roughness of the outermost bump surfaces 106′C1S and 106′C2S of the conductive bumps 106′C1 and 106′C2 is less than that of the outermost electrode surfaces 106′B1S and 106′B2S of the electrodes 106′B1 and 106′B2.

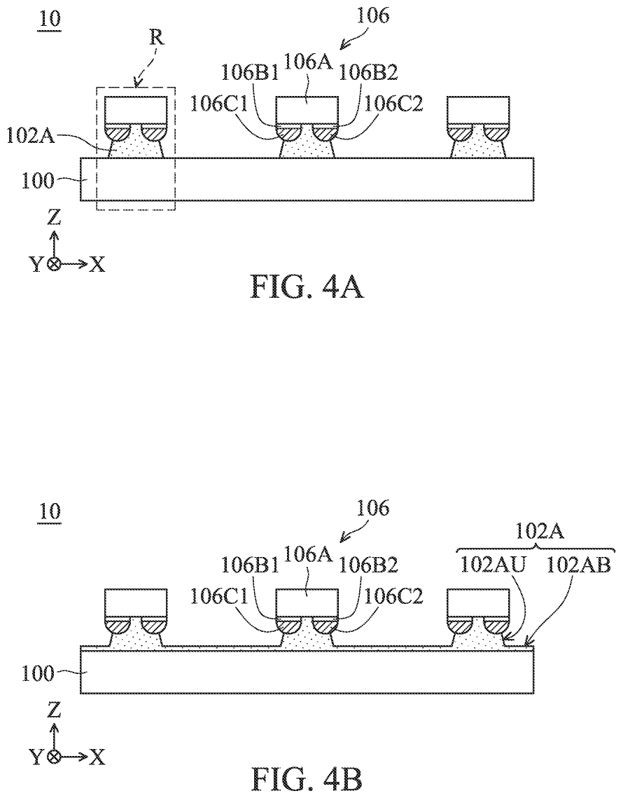

FIGS. 4A and 4B are cross-sectional views of the semiconductor element arrangement structure 10 in accordance with different embodiments. FIGS. 4A and 4B follow FIG. 2. After transferring the semiconductor elements 106, a portion of the adhesive material layer 102 is removed to form adhesive layers 102A that are separated from one another. In some embodiments, an isotropic etching process is used to remove the portion of the adhesive material layer 102. For example, the isotropic etching process may include oxygen plasma etching or oxygen plasma etching with fluorine radicals. During the process of removing the adhesive material layer 102, the semiconductor stacks 106A of the semiconductor elements 106 may be used as etching masks so that the portions of the adhesive material layer 102 that are shielded by the semiconductor elements 106 are preserved.

As shown in FIG. 4A, after the formation of the adhesive layers 102A, the semiconductor elements 106 are disposed on the adhesive layers 102A in a one-to-one configuration, and each of the adhesive layers 102A is in direct contact with the sides of the electrodes 106B1 and 106B2. Moreover, in one embodiment, the adhesive layers 102A are in direct contact with the conductive bumps 106C1 and 106C2 as well. In addition, in some embodiments, after the formation of the adhesive layers 102A, the electrodes 106B1 and 106B2 and portions of the conductive bumps 106C1 and 106C2 of the semiconductor elements 106 are exposed and not covered by the adhesive layers 102A. That is, the adhesive layers 102A only partially cover the conductive bumps 106C1 and 106C2.

In FIG. 4A, the semiconductor elements 106 are disposed on the adhesive layers 102A, which can prevent the semiconductor element 106 from being pulled to change its position by the adhesive layer 102A below a neighboring semiconductor element 106.

Referring to FIG. 4B, the adhesive layer 102A between the semiconductor elements 106 is not completely removed by etching, and thus the carrier substrate 100 is not exposed. In particular, the adhesive layer 102A includes a base portion 102AB located between the semiconductor elements 106 and upper portions 102AU located directly below the semiconductor elements 106. The upper portions 102AU is connected with one another through the base portion 102AB. In some embodiments, with a control of the etching time of the adhesive material layer 102 in FIG. 2, a portion of the adhesive material layer 102 between the semiconductor elements 106 is preserved to form the base portion 102AB of the adhesive layer 102A shown in FIG. 4B. In some embodiments, the top surface of the base portion 102AB is lower than the lowest elevation at which the conductive bumps 106C1 and 106C2 are located. Accordingly, the base portion 102AB is separated from and not directly connected to the conductive bumps 106C1 and 106C2.

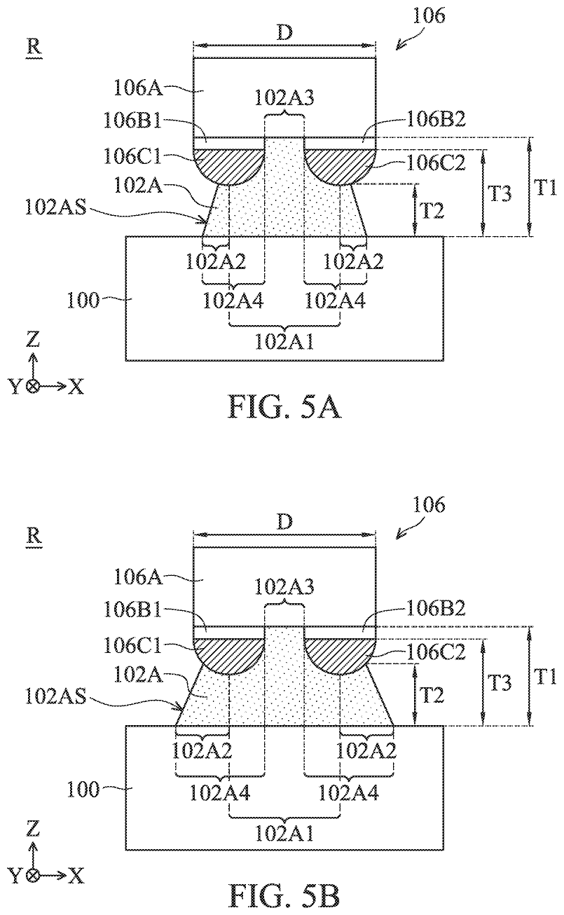

FIGS. 5A-5D are enlarged cross-sectional views of the region R in FIG. 4A in accordance with different embodiments. Referring FIG. 5A, in some embodiments, the adhesive layer 102A has a tilted sidewall 102AS. Specifically, in one embodiment, the width of the adhesive layer 102A gradually decreases along the direction away from the carrier substrate 100 (e.g., along the Z-axis direction in FIG. 5A). In FIG. 5A, the semiconductor element 106 has a maximum horizontal width D, and the adhesive layer 102A has a maximum horizontal width that is equal to the sum of the maximum horizontal width of a first portion 102A1 and two second portions 102A2 of the adhesive layer 102A. In some embodiments, the projected plane of the adhesive layer 102A on the carrier substrate 100 falls within the projected plane of the semiconductor element 106 on the carrier substrate 100. That is, as shown in FIG. 5A, the maximum horizontal width of the adhesive layer 102A is less than the maximum horizontal width D of the corresponding semiconductor element 106. Furthermore, in some embodiments, the adhesive layer 102A completely fills the space between the electrodes 106B1 and 106B2 and the space between the conductive bumps 106C1 and 106C2. Therefore, the adhesive layer 102A directly contacts the insulating layer (not shown in FIG. 5A) of the semiconductor element 106.

As shown in FIG. 5A, in some embodiments, the adhesive layer 102A has the first portion 102A1 between the conductive bumps 106C1 and 106C2 (for example, between a lowest point of the conductive bump 106C1 of the semiconductor element 106 and a lowest point of the conductive bump 106C2 of the semiconductor element 106) of the semiconductor element 106, and has the second portion 102A2 not between the conductive bumps 106C1 and 106C2. The first portion 102A1 and the second portion 102A2 have maximum thicknesses T1 and T2, respectively. The maximum thickness T1 of the first portion 102A1 is greater than the maximum thickness T2 of the second portion 102A2.

Referring again to FIG. 5A, in some embodiments, the adhesive layer 102A has a third portion 102A3 between the electrodes 106B1 and 106B2 (for example, between a boundary (e.g., right boundary) of the electrode 106B1 of the semiconductor element 106 and a boundary (e.g., left boundary) of the electrode 106B2 of the semiconductor element 106) of the semiconductor element 106, and has a fourth portion 102A4 not between the electrodes 106B1 and 106B2. The third portion 102A3 and the fourth portion 102A4 have the maximum thickness T1 and a maximum thickness T3, respectively. The maximum thickness T1 of the third portion 102A3 is greater than the maximum thickness T3 of the fourth portion 102A4.

Referring to FIG. 5B, the embodiment shown in FIG. 5B is similar to that shown in FIG. 5A. But, in FIG. 5B, the projected plane of the semiconductor element 106 on the carrier substrate 100 falls within the projected plane of the adhesive layer 102A on the carrier substrate 100. Measured from the top point of view (not shown), the projected plane of the adhesive layer 102A on the carrier substrate 100 is greater than that of the corresponding semiconductor element 106 on the carrier substrate 100. That is, as shown in FIG. 5B, the maximum horizontal width of the adhesive layer 102A, which is equal to the sum of the maximum horizontal width of the first portion 102A1 and two second portions 102A2 of the adhesive layer 102A, is greater than the maximum horizontal width D of the semiconductor element 106. The dimensional configuration can be achieved by controlling the etching rate and etching time.

Referring to FIG. 5C, the embodiment shown in FIG. 5C is similar to that shown in FIG. 5B. But, the adhesive layer 102A shown in FIG. 5C has a curved profile. In one embodiment, the adhesive layer 102A shown in FIG. 5C has a concave profile. In other words, the sidewall 102AS of the adhesive layer 102A is recessed inwardly.

Referring to FIG. 5D, the embodiment shown in FIG. 5D is similar to that shown in FIG. 5C, except that the adhesive layer 102A in FIG. 5D does not completely fill the space between the electrodes 106B1 and 106B2. Therefore, a void 108 remains between the semiconductor element 106 and the adhesive layer 102A. In this embodiment, the void 108, the space between the electrodes 106B1 and 106B2, exposes portions of the electrodes 106B1 and 106B2. In some embodiments, the adhesive layer 102A fills less between the electrodes 106B1 and 106B2. The void 108 exposes portions of the electrodes 106B1 and 106B2 and portions of the conductive bumps 106C1 and 106C2.

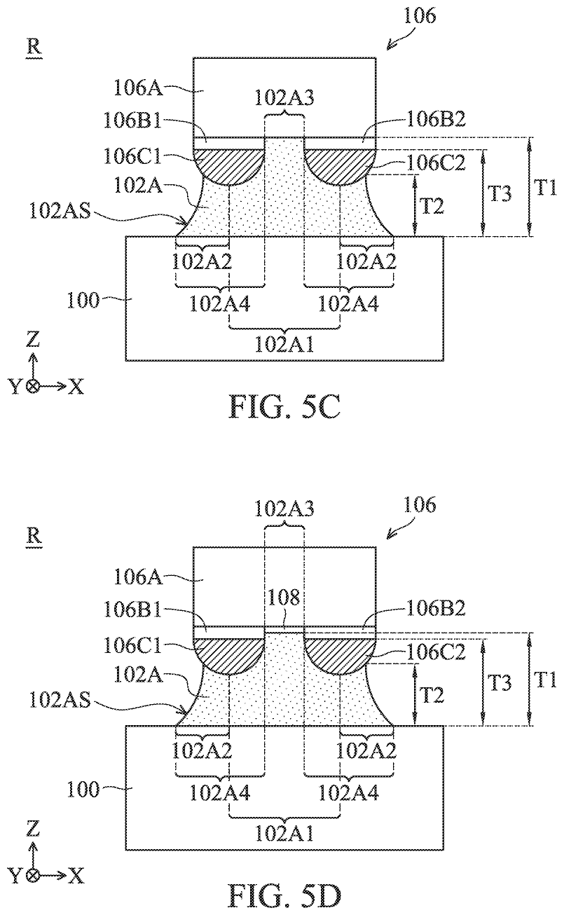

FIGS. 6 and 7 show the processes of transferring the semiconductor elements 106 from the carrier substrate 100 to a target substrate 110 in accordance with some embodiments. Referring to FIG. 6, in the semiconductor element arrangement structure 10, a plurality of semiconductor elements 106 are fixed to the carrier substrate 100 in an array through the adhesive layers 102A. Although a one-dimensional array is shown in FIG. 6, the semiconductor elements 106 can be arranged in a two-dimensional array in a top view. The semiconductor elements 106 are picked up from the carrier substrate 100 by a pickup tool 200. As shown in FIG. 6, before transferring, each semiconductor element 106 is fixed to the carrier substrate 100 through one adhesive layer 102A. The pickup tool 200 includes a base 202. The base 202 has protruding portions 202a arranged in a specific pitch. For example, in some embodiments, as shown in FIG. 6, in a one-dimensional direction (e.g., the X-axis direction in FIG. 6), the protruding portions 202a are arranged in a pitch corresponding to the distance between two semiconductor elements 106. The protruding portions 202a can be formed in a varying pitch arrangement according to actual processing requirement. For example, the protruding portions 202a can be arranged in a pitch corresponding to a distance between three, four, five or more semiconductor elements 106. The base 202 with the protruding portions 202a arranged in a specific pitch is capable of transferring semiconductor elements 106 arranged in the specific pitch to the target substrate. The non-transferred semiconductor elements 106 can be kept to use in other process.

In some embodiments, the base 202 includes a flexible material of adhesive polymer for attaching to the semiconductor elements 106. Specifically, the flexible material includes a poly-siloxane-based material, such as polydimethylsiloxane (PDMS). However, in other embodiments, the base 202 includes a non-stick material. For example, in some embodiments, the non-stick material includes silicon oxide (SiOₓ), silicon nitride (SiNₓ), or silicon oxynitride (SiOₓN_{y}).

In the embodiments, the base 202 includes the non-stick material, as shown in FIG. 6, the pickup tool 200 further includes an adhesive layer 204 disposed on the surface of the protruding portions 202a of the base 202. In some embodiments, the adhesive layer 204 includes poly-carbonate, polycarbodiimide, epoxy resin, poly-vinyl acetal, acrylic resin, polyester, or a combination thereof.

Referring again to FIG. 6, since the adhesion between the pickup tool 200 and the semiconductor elements 106 is stronger than that between the semiconductor elements 106 and the adhesive layers 102A, the semiconductor elements 106 can be attached to the pickup tool 200 and be detached from the carrier substrate 100.

Next, referring to FIG. 7, the pickup tool 200 transfers the semiconductor elements 106 to the target substrate 110. The semiconductor elements 106 are disposed on the target substrate 110 with the conductive bumps 106C1 and 106C2 facing toward the target substrate 110. In some embodiments, the target substrate 110 is a circuit board applied to a display device, a thin film transistor (TFT) substrate, a substrate with a redistribution layer (RDL), or a sub-mount of a package. In other embodiments, target substrate 110 is a temporary carrier that is similar to the carrier substrate 100. In some embodiments, after transferring the semiconductor elements 106, a bonding process can be performed to bond the semiconductor elements 106 to the target substrate 110. In particular, in one embodiment, the semiconductor elements 106 are bonded to the target substrate 110 through the conductive bumps 106C1 and 106C2 and the conductive structures (not shown) on the target substrate 110 to form electrical connection between the semiconductor elements 106 and the target substrate 110.

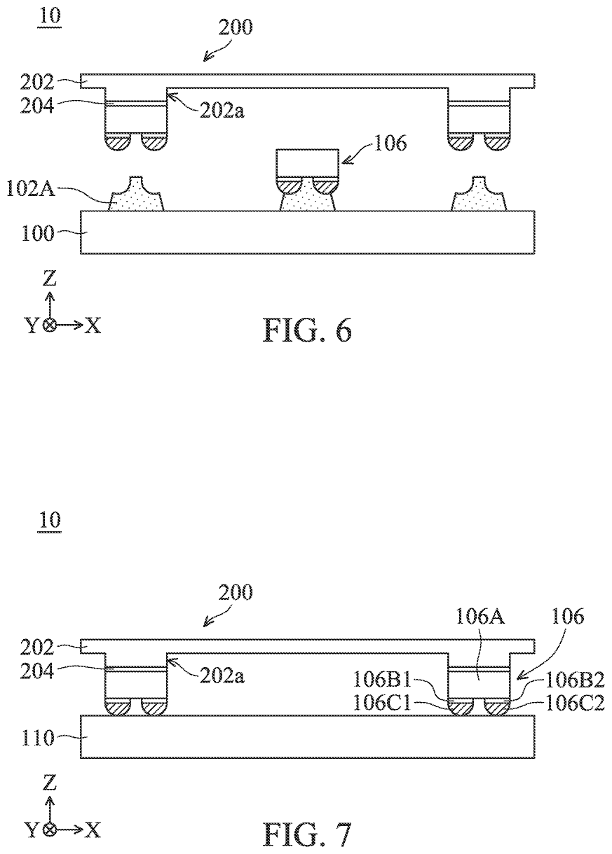

FIG. 8 is a cross-section view of a semiconductor element arrangement structure 20 in accordance with other embodiments. The semiconductor element arrangement structure 20 of FIG. 8 is similar to the semiconductor element arrangement structure 10 of FIG. 2. But, in the semiconductor element arrangement structure 20, a portion of the conductive bumps 106C1 and 106C2 of the semiconductor element 106 sinks into the adhesive material layer 102, and the electrodes 106B1 and 106B2 are exposed. That is, in some embodiments, the conductive bumps 106C1 and 106C2 separate the electrodes 106B1 and 106B2 from the adhesive material layer 102. In some embodiments, as shown in FIG. 8, each of the portions of the conductive bumps 106C1 and 106C2 that sinks into the adhesive material layer 102 has a maximum width W1 along the horizontal direction (e.g., the X-axis direction in FIG. 8), and each of the conductive bumps 106C1 and 106C2 has a maximum width W2. The maximum width W2 is greater than the maximum width W1. When the maximum width W1 is less than the maximum width W2, the adhesion between the conductive bumps 106C1 and 106C2 and the adhesive material layer 102 becomes inferior, which is beneficial to transferring the semiconductor elements 106.

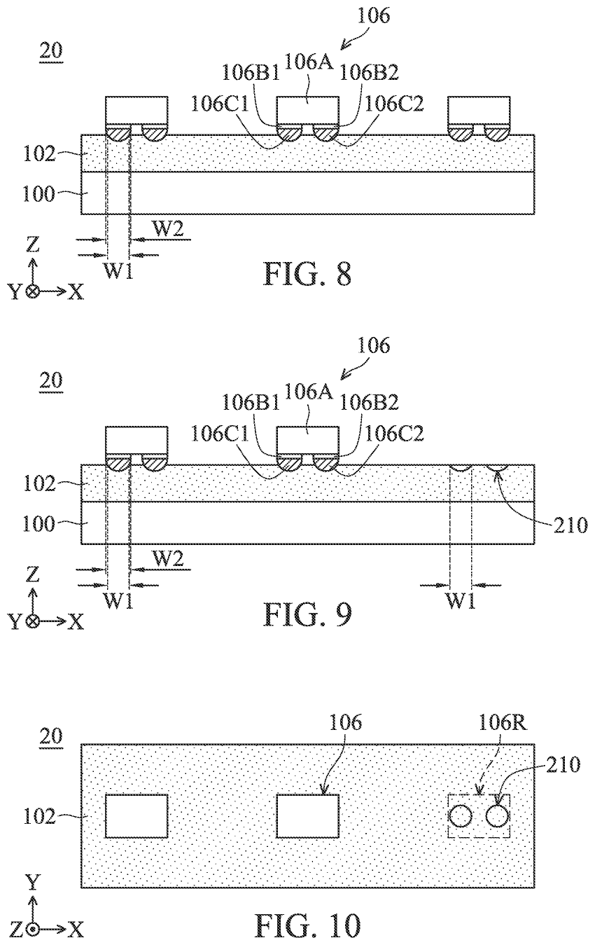

FIGS. 9 and 10 are a cross-sectional view and a top view of the semiconductor element arrangement structure 20, respectively, after transferring the semiconductor elements 106 in accordance with other embodiments. Referring to FIG. 9, some semiconductor elements 106 are transferred from the carrier substrate 100 by the transferring process shown in FIG. 6. In some embodiments, as shown in FIG. 9, after transferring the semiconductor element 106, indentations 210 left by the conductive bumps 106C1 and 106C2 are formed on the surface of the adhesive material layer 102. In some embodiments, the indentation 210 has the maximum width W1 along the horizontal direction (e.g., the X-axis direction in FIG. 9) as well.

Next, referring to FIG. 10, in a top view of the semiconductor element arrangement structure 20, after transferring the semiconductor element 106, a removal region 106R is shown or defined by the region on the adhesive material layer 102 where the transferred semiconductor element 106 is originally located. The projected area of the removal region 106R on the carrier substrate is substantially equal to that of the semiconductor element 106 on the carrier substrate. In addition, in some embodiments, When the projected area of the indentations 210 on the carrier substrate is less than 20% of the projected area of the corresponding removal region 106R on the carrier substrate, the semiconductor elements 106 can be prevented from failing to detach from the carrier substrate and attach to the pickup tool.

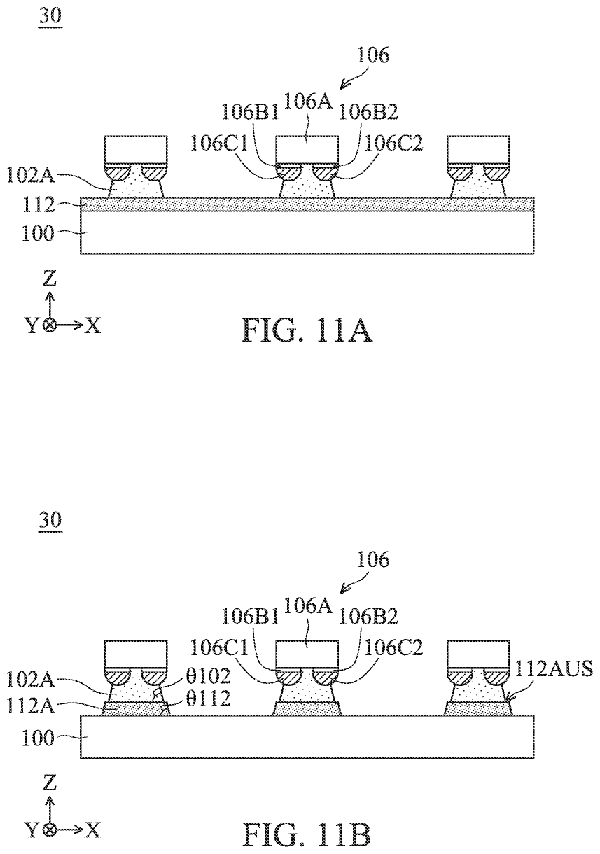

FIGS. 11A and 11B are cross-sectional views of a semiconductor element arrangement structure 30 in accordance with some embodiments. Referring to FIG. 11A, the semiconductor element arrangement structure 30 is similar to the semiconductor element arrangement structure 10 of FIG. 4A. But, the semiconductor element arrangement structure 30 further includes a release layer 112. The release layer 112 is located between the carrier substrate 100 and the adhesive layers 102A. In the subsequent transferring process, a portion of the release layer 112 is degraded by an irradiation of a laser beam so that the semiconductor elements 106 to be transferred are capable of removing from the carrier substrate 100. In some embodiments, the material of the release layer 112 includes an inorganic material that can be degraded by laser, such as silicon nitride, gallium nitride, or a combination thereof. In other embodiments, when the subsequent transferring process of the semiconductor elements 106 uses an infrared ray, the release layer 112 includes an organic polymer material, such as polyimide (PI), epoxy resin, acrylic resin, or silicone, that can be degraded by the infrared ray.

Referring FIG. 11B, the embodiment of FIG. 11B is similar to that of FIG. 11A. But, the semiconductor element arrangement structure 30 in FIG. 11B includes discrete release layers 112A. The difference between the discrete release layers 112A in FIG. 11B and the release layer 112 in FIG. 11A is that these discrete release layers 112A are separated from one another, and that each discrete release layer 112A is disposed below the adhesive layer 102A in a one-to-one configuration. Since the semiconductor element 106 has a smaller size, the light used in the subsequent transferring process can confront resolution limits. In other words, owing to the smaller size and the higher density of the semiconductor elements 106 on the carrier substrate 100 and the large light spot generated by the light, the light used in the transferring process is prone to irradiate adjacent non-transferred semiconductor elements 106. Accordingly, the adjacent non-transferred semiconductor elements 106 will unintentionally be detached from the carrier substrate 100, thereby decreasing the production yield. The adaption of discrete release layers 112A can avoid an over degradation occurring on the release layers 112 around the irradiated semiconductor elements 106. Therefore, the semiconductor elements 106 within a predetermined region are capable of being precisely transferred from the carrier substrate 100, on which the semiconductor elements 106 are disposed in high density, to the target substrate.

In some embodiments, a portion of the release layer 112 as shown in FIG. 11A can be removed to form the discrete release layers 112A as shown in FIG. 11B along the process of removing the aforementioned adhesive material layer 102 to form the adhesive layers 102A. In other embodiments, the adhesive material layer 102 and the release layer 112 can be removed using the same etching method or different etching methods in different etching processes.

In some embodiments, since the adhesive layers 102A and the discrete release layers 112A have different etching rates, the adhesive layers 102A and the discrete release layers 112 have tilted sidewalls with different inclined degrees. In particular, as shown in FIG. 11B, there is an included angle θ102 between the bottom and the sidewall of the adhesive layer 102A, and there is an included angle θ112 between the bottom and the sidewall of the discrete release layer 112A. The included angle θ112 of the discrete release layer 112A is greater than the included angle θ102 of the adhesive layer 102A. In addition, although not explicitly illustrated in FIG. 11B, in some embodiments, the outer profile of the sidewall of the discrete release layer 112A has a curved shape. Specifically, the outer profile of the discrete release layer 112A is a concave surface. Furthermore, in some embodiments, the adhesive layers 102A do not fully cover the top surfaces 112AUS of the discrete release layers 112A. After the aforementioned etching step, portions of the top surfaces 112AUS of the discrete release layers 112A are exposed.

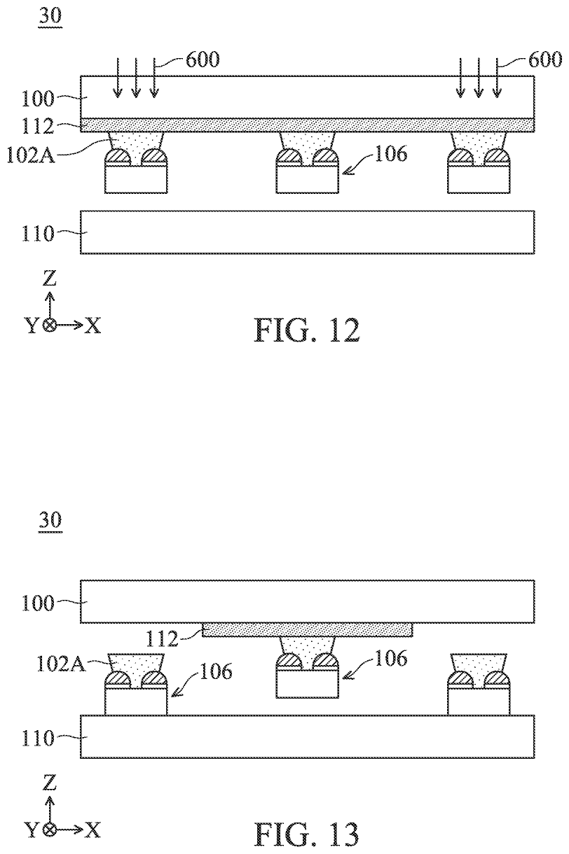

FIGS. 12 and 13 show the process of transferring the semiconductor elements 106 from the carrier substrate 100 to the target substrate 110 in accordance with other embodiments. Referring to FIG. 12, the semiconductor element arrangement structure 30 in FIG. 11A is inverted so that the semiconductor stacks of the semiconductor elements 106 face toward the target substrate 110. Subsequently, a laser beam 600 is focused on a position of the release layer 112 where semiconductor element 106 is aimed to transfer. In FIG. 12, the semiconductor element arrangement structure 30 is suspended above the target substrate 110 and is not in direct contact with the target substrate 110. In other embodiments, the semiconductor element arrangement structure 30 can be placed on the target substrate 110 so that the semiconductor element arrangement structure 30 is in direct contact with the target substrate 110. Afterwards, the laser beam 600 is applied to degrade the release layer 112.

Referring to FIG. 13, after being irradiated by the laser beam 600, the semiconductor elements 106 are transferred to the predetermined positions on the target substrate 110. The semiconductor elements 106 that are not irradiated by the laser beam 600 are remained on the carrier substrate 100. As shown in FIG. 13, after transferring the semiconductor elements 106, the adhesive layers 102A remain on the semiconductor elements 106. In some embodiments, an etching process (e.g., an oxygen plasma etching process) is performed to remove the adhesive layers 102A on the semiconductor elements 106, or an organic solvent can be used to dissolve the adhesive layers 102A without damaging the semiconductor elements 106.

In summary, in some embodiments of the application, the semiconductor element arrangement structure includes discrete adhesive layers that are separated from one another. The semiconductor elements are disposed on the adhesive layers in a one-to-one configuration. Since the contact area between the semiconductor elements and the adhesive layers is smaller, the semiconductor elements to be transferred can be readily detached from the carrier substrate during the transfer of the semiconductor elements. Accordingly, the accuracy and efficiency of the mass transfer of semiconductor elements can increase.

Although some embodiments of the application and their advantages have been described in detail, it should be understood that various changes, substitutions and alterations can be made herein without departing from the spirit and scope of the application. The features between embodiments of the application can be arbitrarily applied to one another without departing from the spirit and scope of the application. Moreover, the scope of the present application is not intended to be limited to the particular embodiments of the process, machine, manufacture, composition of matter, means, methods and steps described in the specification. As a person having ordinary skill in the art will readily appreciate from the application, processes, machines, manufacture, compositions of matter, means, methods, or steps, presently existing or later to be developed, that perform substantially the same function or achieve substantially the same result as the corresponding embodiments described herein may be utilized according to the application. Accordingly, the appended claims are intended to include within their scope such processes, machines, manufacture, compositions of matter, means, methods, or steps. The scope of the present application shall be defined by the appended claims. Any one of embodiments or claims of the present application do not have to achieve all the aspects, advantages or features disclosed in the application.

What is claimed is:

1. A semiconductor element arrangement structure, comprising:
a carrier substrate;
a first adhesive layer and a second adhesive layer respectively disposed on the carrier substrate and separated from each other; and
a first semiconductor element and a second semiconductor element disposed on the first adhesive layer and the second adhesive layer, respectively,
wherein, the first semiconductor element has a first electrode and a second electrode on a same side of the first semiconductor element;
the second semiconductor element has a third electrode and a fourth electrode on a same side of the second semiconductor element;
the first adhesive layer is in direct contact with the first electrode and the second electrode, and the second adhesive layer is in direct contact with the third electrode and the fourth electrode; and
the first adhesive layer has a first thickness between the first electrode and the second electrode and a second thickness not between the first electrode, and the second electrode that is less than the first thickness.

2. The semiconductor element arrangement structure of claim 1, wherein the carrier substrate is light-transmittable to light from the first semiconductor element.

3. The semiconductor element arrangement structure of claim 1, wherein the first semiconductor element is electrically isolated from the carrier substrate.

4. The semiconductor element arrangement structure of claim 1, wherein the first adhesive layer has a width gradually decreasing along a direction away from the carrier substrate.

5. The semiconductor element arrangement structure of claim 1, wherein the first adhesive layer has a curved sidewall in a cross-sectional view.

6. The semiconductor element arrangement structure of claim 1, wherein the first semiconductor element comprises a first conductive bump and a second conductive bump disposed on the first electrode and the second electrode, respectively, and each of the first conductive bump and the second conductive bump has a curved profile.

7. The semiconductor element arrangement structure of claim 1, further comprising a release layer disposed between the carrier substrate and the first adhesive layer.

8. The semiconductor element arrangement structure of claim 7, wherein the release layer comprises an inorganic material.

9. The semiconductor element arrangement structure of claim 1, further comprising a first release layer and a second release layer which are separated from each other, and disposed under the first adhesive layer and the second adhesive layer, respectively.

10. The semiconductor element arrangement structure of claim 1, further comprising an auxiliary adhesive layer located between the carrier substrate and the first adhesive layer and a base material layer located between the auxiliary adhesive layer and the first adhesive layer.

11. The semiconductor element arrangement structure of claim 1, further comprising two indentations and a corresponding removal region defined on the carrier substrate, and a projected area of the two indentations on the carrier substrate is less than 20% of a projected area of the corresponding removal region on the carrier substrate in a top view.

12. The semiconductor element arrangement structure of claim 9, further comprising a first included angle between a bottom and a sidewall of the first adhesive layer, and a second included angle between a bottom and a sidewall of the first release layer, wherein the first included angle is different from the second included angle in a cross-sectional view.

13. The semiconductor element arrangement structure of claim 12, wherein the second included angle is greater than the first included angle.

14. The semiconductor element arrangement structure of claim 6, wherein, in a cross-sectional view, the first conductive bump further comprises a first maximum width and a portion sinking into the adhesive layer, the portion comprises a second maximum width along a horizontal direction, and the first maximum width is greater than the second maximum width.

15. The semiconductor element arrangement structure of claim 1, wherein, in a cross-sectional view, the first adhesive layer comprises a first maximum width, and the first semiconductor element comprises a second maximum width, and the first maximum width is different from the second maximum width.

16. The semiconductor element arrangement structure of claim 15, wherein the first maximum width is greater than the second maximum width.

17. The semiconductor element arrangement structure of claim 15, wherein the first maximum width is located at a bottommost surface of the first adhesive layer.

18. The semiconductor element arrangement structure of claim 1, wherein the first adhesive layer has a tilted sidewall in a cross-sectional view.

19. The semiconductor element arrangement structure of claim 1, further comprising a void located between the first semiconductor element and the first adhesive layer such that portions of the first electrode and the second electrode are exposed in the void.

20. The semiconductor element arrangement structure of claim 1, further comprising a third adhesive layer disposed on the carrier substrate and a third semiconductor element disposed on the third adhesive layer, wherein the first semiconductor element is spaced apart from the second semiconductor element by a first distance, and the first semiconductor element is spaced apart from the third semiconductor element by a second distance which is substantially equal to the first distance.
